(19) United States
(12) Patent Application Publication
(10) Pub. No.: US 2012/0048345 A1
(43) Pub. Date: Mar. 1, 2012

(54) ARRAY OF PHOTOVOLTAIC ASSEMBLIES

(76) Inventors: Michael Wood, Flemington, NJ (US); Michael Wood, III, Frenchtown, NJ (US)

(21) Appl. No.: 13/097,476

(22) Filed: Apr. 29, 2011

Related U.S. Application Data
(60) Provisional application No. 61/402,370, filed on Aug. 30, 2010.

(51) Int. Cl. H01L 31/042; H01L 31/02; H01L 31/05

(52) U.S. Cl. 136/251

(57) ABSTRACT

An array of photovoltaic assemblies places photovoltaic panels in spaced rows. The array has a number of supports, each support including: (a) a first member with an upper support surface for supporting the neighboring side edges of an adjacent pair of photovoltaic panels located in one of the rows; (b) a second member with a lower support surface disposed at an acute angle relative to the upper support surface, and connecting to the first member at a front joint; and (c) a third member spaced from the front joint and connected between the first and the second member. At least one front tray is disposed next to the front edge of photovoltaic panels in front. A number of back trays and a number of inclined deflector sections are arranged together in a plurality of ranks. These ranks are interleaved with the spaced rows of photovoltaic panels. The back trays in each of the ranks are aligned. The inclined deflector sections extend up to the back edge of a corresponding one of said photovoltaic panels.

### CROSS-REFERENCES TO RELATED APPLICATIONS

This application claims the benefit of U.S. Provisional Patent Application Ser. No. 61/402,370, filed 30 Aug., 2010, the contents of which are hereby incorporated by reference herein.

### BACKGROUND OF THE INVENTION

1. Field of the Invention

The present invention relates to arrays of photovoltaic panels, and in particular, to structures for securely mounting such panels.

2. Description of Related Art

Global circumstances of both an environmental and economic nature have resulted in a significant demand for alternative energy sources for providing electricity to both residential and commercial entities. Solar energy, culled from the sun by use of polycrystalline solar panels, has proven to be one of the most productive and economical means of satisfying this requirement.

A critical component of any solar panel mounting system is its ability to safely withstand nature's forces over an extended useful life. The primary danger to the mounting system is wind and precipitation forces. Wind forces are foreseeable to the extent of storm generated speeds. For this reason, certifications required by governmental enforcement authorities often require the system to withstand speeds of up to 120 mph.

A pressing problem has been the challenge of installing solar panels on flat roofing systems. The first generation of solar panel racking systems has been bolted into the roof. This resulted in storm water penetration problems. Additionally, bolting into the existing roofing system required prolonged pre-inspection and design periods need to identify hidden structural components for accomplishing proper mounting. Consequently, the construction/installation phase that followed required higher labor times to install the systems.

Furthermore, existing roof equipment (air control) or protrusions, (exhaust pipes) leave a wide array of irregular roof space available for panel use.

Previous systems relied upon racking systems that required the panel to be exposed to the sun in the “portrait” position (i.e. longer edges of a rectangular panel tilted, and shorter edges horizontal). This reduced the design flexibility and limited the amount of roof space that could be used in certain applications.

Ballast systems came into use in an attempt to solve the roof penetration and leaking problems. However, these systems, could not fully achieve the required wind force certifications. Consequently, partial bolting was needed, in part, because indiscriminately adding ballast would produce unsafe loads on the roof. However, partial bolting resulted in the same pre-construction inspections and high labor costs.

A delicate balance exists between the advantages of weighting the mounting system, to overcome wind forces, and the disadvantage that this weight (load) will apply to the structure it rests upon. As most solar panel systems are mounted on roofs, and the largest systems mounted on commercial roofs, which are typically flat, weight distribution is a critical consideration. A danger exists in placing heavy systems on flat roofs that can suffer a wide range of environmental forces, especially in the northeast, where snow and ice is known to accumulate over the winter months. Load forces are also considered and calculated by the introduction of wind forces on the solar panel system as a whole. When wind forces strike the system, it is pushed into the roof and additional forces are therefore added to the net weight of the system in total.

See also U.S. Pat. Nos. 5,746,839; 6,105,316; 6,606,823; 6,968,654; 7,806,377; 7,847,185; 7,905,227; and RE38988, as well as US Patent Application Publication Nos. 2003/0164187; 2004/0250491; 2007/0144575; and 2010/0212714

### SUMMARY OF THE INVENTION

In accordance with the illustrative embodiment demonstrating features and advantages of the present invention, there is provided an array of photovoltaic assemblies. The array includes a plurality of photovoltaic panels arranged in a plurality of spaced rows. The spaced rows include a frontal one and a posterior one. Each of the photovoltaic panels have a back edge, a front edge and an opposite pair of side edges. The array also includes a plurality of supports, each with a lower support surface and an upper support surface. The upper support surface is disposed at an acute angle relative to the lower support surface. The upper support surface is adapted to provide support for a neighboring pair of side edges of an adjacent pair of photovoltaic panels located in one of the spaced rows. The array also includes at least one front tray disposed next to the front edge of the photovoltaic panels in the frontal one of the rows. The array also has a back structure including a plurality of back trays and a plurality of inclined deflector sections. The back trays and the inclined deflector sections are arranged in a plurality of ranks. The plurality of ranks and the spaced rows of photovoltaic panels are interleaved. The back trays in each of the ranks are aligned. The inclined deflector sections extend up to the back edge of a corresponding one of the photovoltaic panels.

According to another aspect of the invention, there is provided an array of photovoltaic assemblies having a plurality of photovoltaic panels arranged in a plurality of spaced rows. The spaced rows include a frontal one and a posterior one. Each of the panels have a back edge, a front edge and an opposite pair of side edges. The array includes a plurality of back trays arranged in a plurality of ranks. The plurality of ranks and the spaced rows of photovoltaic panels are interleaved. The back trays in each of the ranks are aligned. The array includes a plurality of supports, that each include: (a) a first member having an upper support surface adapted to provide support for a neighboring pair of side edges of an adjacent pair of photovoltaic panels located in one of the spaced rows; (b) a second member with a lower support surface disposed at an acute angle relative to the upper support surface, and connecting to the first member at a front joint; and (c) a third member spaced from the front joint and connected between the first and the second member.

By employing apparatus of the foregoing type, an improved mounting system is achieved. In a disclosed embodiment multiple rows of photovoltaic panels are mounted on supports that hold the panels at an angle (e.g., 5°, 10° or 20° from horizontal). To achieve that angular position, the supports have an inclined member connected to one end of a horizontal member that rests on the roof. Rising from the other end of the horizontal member is a back member that connects to the inclined member at an oblique angle. The support to support spacing (right to left) matches the width of the photovoltaic panels, so that a pair of supports can support a panel, one support on the right and another support on the left. Moreover, each support is wide enough to serve two adjacent panels, that is, the right edge of one panel and the left edge of an adjacent panel.

The disclosed embodiment has means for mechanically interconnecting the panel assemblies. This creates a finished product that offers total connectivity and therefore resists wind forces as a total unit, rather then as an individual unit or in “zones.” It was discovered that the mode of connectivity greatly contributed to the system's ability to withstand wind forces.

The disclosed embodiment achieves significant stability by interconnecting rows and columns of panel supports, so that each support lends additional reinforcement to its neighbors. The disclosed interconnection is achieved with multiple ranks of aligned ballast trays that simultaneously connect to multiple supports in one row and multiple supports in an adjacent row (except for trays constituting a border of the array). Effectively, each support is connected in some way to every other support.

When ballast weights are placed in the trays the entire structure is highly stable and secure. In some embodiments an auxiliary tray is connected from the midsection of one support to the midsection of an adjacent support so that ballast weight can be strategically distributed in such a manner as to increase overall stability.

In the disclosed embodiment the supports are aligned in columns and rows and the length (right to left dimension) of each tray matches the support to support spacing in a row. Consequently, aligned trays (either abutting or overlapping) can be simultaneously fastened at their junction to the front of a support in one row and to the back of a support in an adjacent row.

To minimize the destabilizing effect of wind forces, the disclosed embodiment has an inclined deflector section. The disclosed deflector is a steel panel that is attached to the back of two or more supports. These deflectors are arranged to substantially eliminate significant gaps that would allow wind to travel under and lift the photovoltaic panels.

In this embodiment, the upper edge of the deflector section has an overhanging piece that hooks over the back edge of a photovoltaic panel to hold it in place. Also, the front of the inclined support has a hook for gripping the front edge of photovoltaic panels mounted on the support. Therefore, the panels can be held without bolting into them.

Ballast in the form of concrete blocks or paving bricks is placed in the ballast trays to provide the desired weight. The disclosed system therefore does not require any roof penetration, does not require traditional use of bolting into the structure it sits upon, and significantly saves on installation time. While governmental authorities have mandated that the additional load caused by the photovoltaic array be limited to 5 lbs/ft² (24 kg/m²), the weight of the present system can be well below 3 lbs/ft² (15 kg/m²). Also, the present arrangement has the flexibility to allow panel orientation at 5°, 10° or 20° and installation in either the portrait or landscape orientation. The system can be pre-assembled before shipment and greatly reduces current installation labor demands.

Advantages also are achieved with respect to storm water or precipitation problems. These problems arise from the penetration of a roofing system by bolts and are especially problematic in flat commercial roofs, where water drainage is critical by design. However, the subject design overcomes this problem since it is a ballast system that requires no bolting into sub-surface structural components of the building it rests upon.

In addition, the disclosed mounting system provides substantial savings in labor costs. Again, roof mounting through penetration, so as to connect mechanically to sub-surface structural members, was very time consuming. It required a detailed examination of the roofs framing system, planning and architectural as-built drawings, engineering analysis and, finally, labor to locate the sub-surface members during installation. Then, careful drilling and bolting along with sealing efforts had to be undertaken to attach the solar panel mounting system. The present invention avoids these labor requirements.

Labor is further reduced by the method of attaching the solar panels to the disclosed mounting system. The common and traditional industry method is to use brackets that can be adjusted along a rail system. However, this requires additional labor to both install the bracket (a separate part) and to make the adjustment of the bracket in the field. The present arrangement is flexible and can be customized at the factory. The specific dimensions of the chosen solar panel can be accommodated during fabrication of the mounting system. This avoids the need for brackets or adjustments by the labor force in the field.

By adjusting the length of the ballast trays and adjusting the length and configuration of the inclined supports, the orientation to the sun and the positioning on the supports is readily accomplished without adjustments in the field.

The system in question, by means of the above improvements as mentioned above, does not require the traditional, extensive efforts undertaken for a roof mounted system. Labor costs can be cut an estimated 45%.

The present system is unlike prior mounting systems that were restricted to a single orientation (landscape or portrait). A system that is limited to a single orientation will fail, in many cases, to occupy all available roof space. This is because most commercial roofs have areas that are already occupied by building equipment, such as air control units, ventilation or exhaust risers, access ports and skylights. Since most buildings were constructed before the popular use of solar panels, no forethought to the placement of these devices was made with respect to mounting systems. Accordingly, more often than not, solar panel mounting systems must be placed in customized patterns around pre-existing objects.

The present system allows flexibility in the choice between placing the panels in a portrait or landscape orientation and allows a designer to maximize available roof space, as well as permitting the panel to be placed at the most favorable angle towards the sun. These adjustments can be accomplished by altering the length of the panel supports and the length of the ballast trays.

### BRIEF DESCRIPTION OF THE DRAWINGS

The above brief description as well as other objects, features and advantages of the present invention will be more fully appreciated by reference to the following detailed description of illustrative embodiments in accordance with the present invention when taken in conjunction with the accompanying drawings, wherein:

FIG. 1 is an exploded perspective view of structure that may be used to support a photovoltaic panel in order to form an array of photovoltaic assemblies in accordance with principles of the present invention;

FIG. 2 is a plan view of the structure of FIG. 1 with photovoltaic panels removed for illustrative purposes;

FIG. 3 is a sectional view taken along line 3-3 of FIG. 2 with central portions broken away for illustrative purposes;

FIG. 4 is a detailed, fragmentary, perspective view of a portion of the support of FIG. 1;

FIG. 5 is a plan view of a structure that is an alternate to that of FIG. 2;

FIG. 6 is a perspective view of the support of FIG. 1, with a repositioned auxiliary tray and an additional wire tray;

FIG. 7 is a detailed, fragmentary, perspective view showing the connection of the wire tray of FIG. 6 to the support; and

FIG. 8 is a plan view showing the structure of FIGS. 1-4 formed into an array of photovoltaic assemblies.

### DETAILED DESCRIPTION

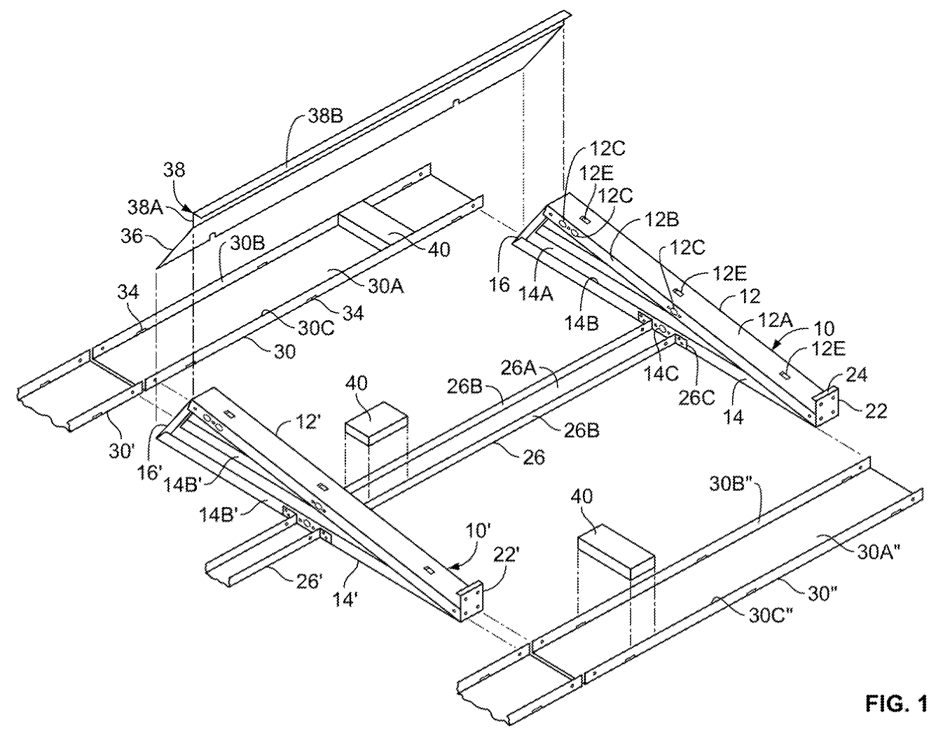

Referring to FIGS. 1-4, the illustrated photovoltaic assembly is designed to be connected in an array with like assemblies. In FIG. 1 two identical supports 10 and 10′ are illustrated. It will be noticed that support 10′ on the left, and its parts, have the same reference numerals as support 10 except for being distinguished by a prime (′).

Support 10 has a first member 12 in the form of a steel channel with its flanges 12B pointing down and its web 12A forming an upper support surface. The front end of channel 12 is shown straddling second member 14, while the back end of channel 12 is shown straddling third member 16. Members 14 and 16 are also channels with channel 14 straddling channel 16.

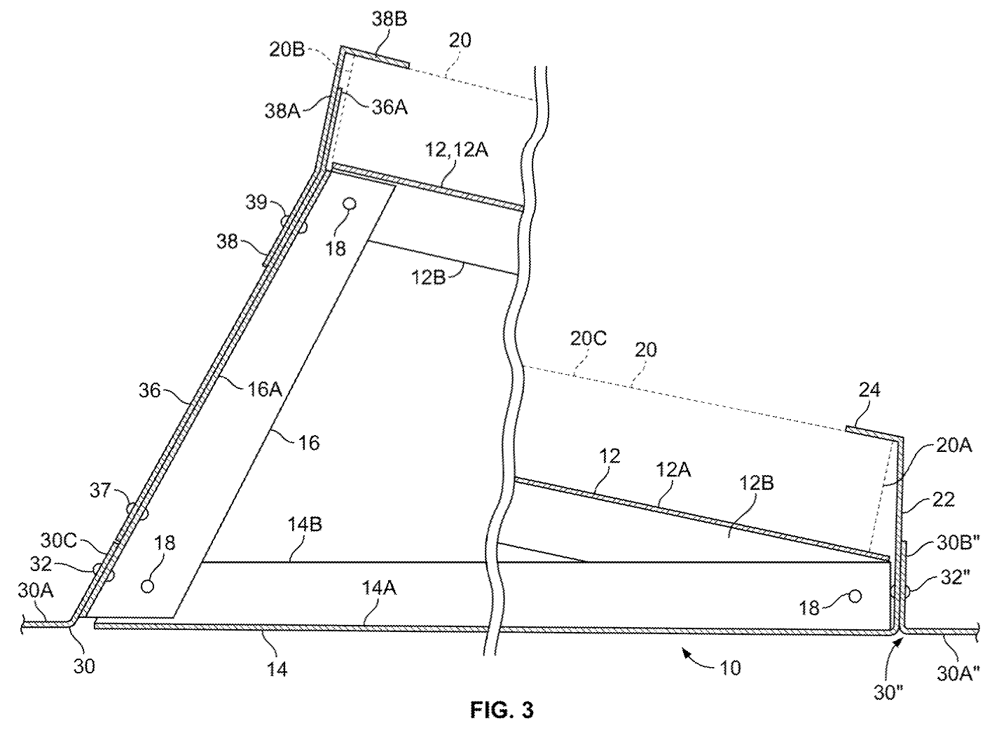

The ends of channels 12, 14 and 16 are fastened together with rivets 18 (FIG. 3) to form a triangular structure. The junction between members 12 and 14 are referred to herein as a front joint. Webs 12A and 14A of channels 12 and 14 are disposed at an acute angle, for example, 5°, 10°, or 20°. Channels 14 and 16 intersect at an acute angle, for example, 60°. The angle between channels 12 and 16 is obtuse.

These angles can be adjusted by the simple expedient of changing the length of one or more of the members 12, 14, or 16. In one embodiment the angles were 60°, 10°, and 110°. In that embodiment the overall length of member 14 was 45 inches (1.14 meters) long, 3 inches (7.6 cm) wide, and the flanges 14B were 1.75 inches (4.4 cm) tall, although other dimension and proportions may be employed in other embodiments, depending on the size of photovoltaic panel 20, the desired angle for the panel, strength requirements, etc. Members 12 and 16 had a similar width and flange height.

Web 14A of channel 14 provides a lower support surface that can rest on a roof either directly or through an intervening elastomeric sheet (not shown). Channels 12 and 14 are provided with knockouts 12C and 14C, respectively, that can be punched out to provide feedthroughs for wires (not shown).

With flanges 14B cut short on the front end, the remaining extended portion of web 14A is bent upwardly into upright branch 22 and backwardly into branch 24 to form a hook for holding the front edge 20A of photovoltaic panel 20 (panel shown in phantom in FIG. 3).

Web 12A has a U-shaped cutout forming a flexible tab 12E that can be bent upwardly as shown in FIG. 4 to provide a spacer for separating neighboring edges of an adjacent pair of photovoltaic panels 20 that may both rest in part on web 12A.

Auxiliary tray 26 is optional and is shown connecting between members 14 and 14′ of supports 10 and 10′. Either end of web 26A of tray 26 is cut short and the extended part of flanges 26B are bent outwardly to form four ears 26C that can be fastened to respective flanges 14B and 14B′. A second auxiliary tray 26′ (identical to tray 26 and also optional) is shown fastened to web 14B′ on the side of member 14′ opposite the side connected to tray 26.

Tray 30 with six weep holes 34 (for shedding rainwater) is shown as a channel with its web 30A integral with upright flange 30B and inclined flange 30C, the latter being attached by rivets 32 to web 16A of member 16. It will be appreciated from FIGS. 1 and 3 that the right end of tray 30 is thus connected to member 16 and that the left end of tray 30 is connected to member 16′.

It will be further appreciated that member 16′ is sufficiently wide so that the left end of tray 30 and the abutting end of identical tray 30′ can both be riveted onto member 16′ together. While trays 30 and 30′ (also referred to as lower troughs) are shown substantially abutting (trays considered abutting even if a minor gap exists), in some embodiments these trays can overlap. The left end of tray 30′ and the right end of an identical tray (not shown) can be together connected to the back of another support similar to support 10′. In this manner, an indefinite number of trays can link together the backs of an indefinite number of supports.

An inclined deflector section is shown with inclined wall 36 lying against web 16A. The upper end of wall 36 extending beyond web 16A is bent back into section 36A. The deflector section also has an upper holder 38 lying against wall 36 and has a section 38A bent back to match section 36A. Holder 38 terminates in an overhang 38B extending perpendicularly from section 38A. Sections 38A and 38B of holder 38 are designed to grip back edge 20B of photovoltaic panel 20. Inclined deflector section 36/38 and tray 30 are referred to collectively as a back structure. Tray 30 is also referred to as a back tray, in that one of its flanges connects to the back of supports 10 and 10′.

The lower right corner of inclined wall 36 is attached to web 16A by rivet 37. The upper right corner of wall 36 and the lower right corner of holder 38 is attached to web 16A by rivet 39. The left end of tray 30, wall 36, and holder 38 will be similarly riveted to member 16′.

It will be appreciated that members 16 and 16′ are sufficiently wide so that for each a second inclined deflector section identical to section 36/38 can be attached to members 16 and 16′ in alignment with and substantially abutting (or overlapping) section 36/38.

In this embodiment support 10, deflector section 36/38 and tray 30 were made of the same gauge of steel product (sheet steel coated with an aluminum-zinc alloy, sold under the trademark Galvalume), although other materials can be used instead.

In this embodiment, tray 30″ is identical to previously mentioned tray 30. Parts of tray 30″ corresponding to those of tray 30 will have the same reference numerals except for being distinguished by a double prime (″). The right end of flange 30B″ is shown in FIG. 3 attached by rivet 32″ to branch 22 of support 10. The left end of flange 30B″ will be similarly attached to branch 22′ of support 10′. Branches 22 and 22′ are sufficiently wide so that at either end of tray 30″ identical trays (one such tray being shown to the left of tray 30″) can be attached to branches 22 and 22′ in alignment with and substantially abutting (or overlapping) tray 30″. In this manner, an indefinite number of trays can link together the fronts of an indefinite number of supports.

Being identical to flange 30C, flange 30C″ of tray 30″ can be attached to the back of other supports in a manner similar to flange 30C in order to start another row of supports. In this manner, an indefinite number of rows of supports and photovoltaic panels can be linked together through intervening trays similar to tray 30″. On the other hand, if no more rows are laid past flange 30C″, then tray 30″ will not connect to the back of any support and will therefore be referred to as a front tray, not a back tray. Accordingly, the row formed by supports 10 and 10′ (and their associated photovoltaic panels 20) will be considered a front row to the extent the front edges of its photovoltaic panels constitute a border beyond which no further panels exist.

Flange 30B of tray 30 may be attached to the front of other supports, in a manner similar to the way flange 30B″ is attached to front branches 22 and 22′ of supports 10 and 10′. In that case, flange 30B will be connecting to another row containing supports similar to supports 10 and 10′ (including associated photovoltaic panels 20). However, flange 30B may be unconnected to other supports so that no new rows are formed, in which case back tray 30 will be considered a rear one of the trays. Also, supports 10 and 10′ (including associated photovoltaic panels 20) will be considered the last row, to the extent the back edges of its photovoltaic panels 20 constitute a border beyond which no further panels exist.

Trays 30, 30″, and 26 are shown with ballast weights 40. Trays 30′ and 26′ may be similarly fitted with ballast weights. Weights 40 may be bricks, paving stones, metal slabs, sandbags, or other items designed to hold down the trays. It has been discovered that ballast weights 40 should be at least as tall as flanges 30A and 30B, which flanges were 1.75 inches (4.4 cm) tall in this embodiment (although other flange heights may be employed in other embodiments). If the ballast weights 40 are too short, then the upper parts of flanges 30A and 30B present a narrow lip that tends to create vortices that make the array more vulnerable to destabilizing wind forces.

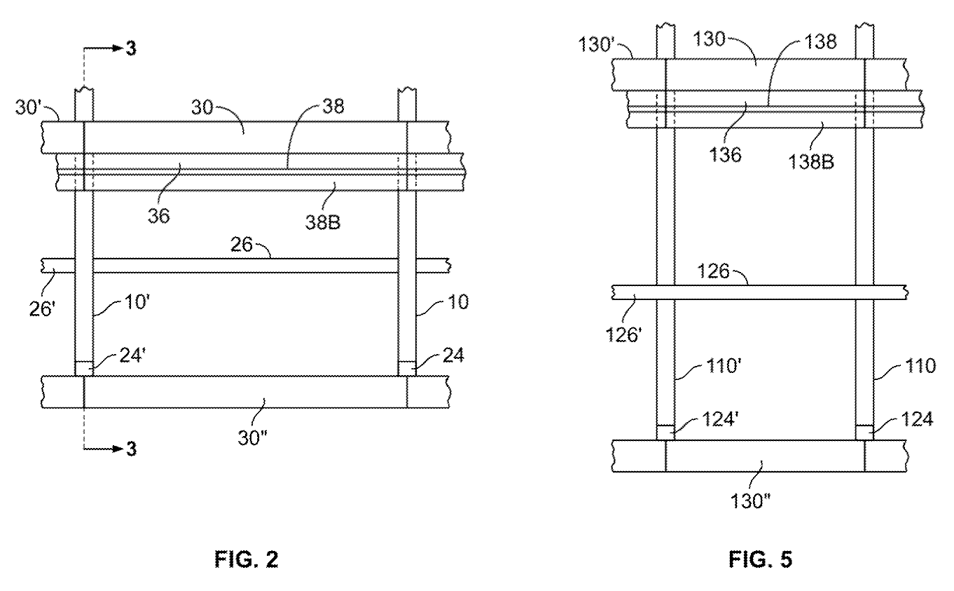

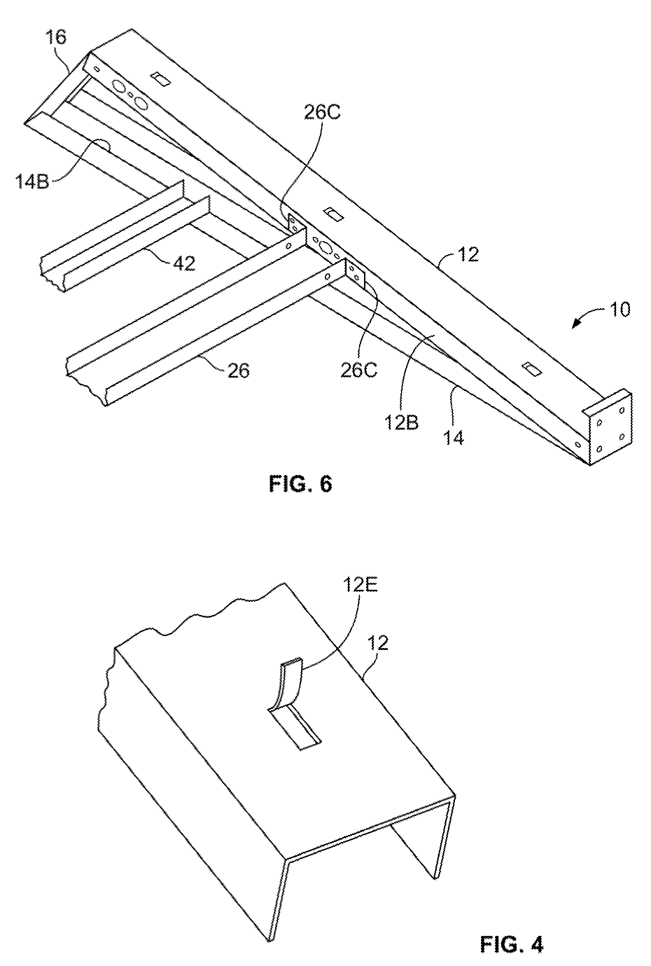

Referring to FIG. 5, the illustrated assembly is comparable to that shown in FIG. 2 and the reference numerals for corresponding components have been increased by 100. In fact, components 126, 130, 130″, 136, 138, and 138B are identical to their correspondents in FIG. 2, except that their lengths (right to left dimensions) have all been decreased by the same amount, while their widths (back to front dimensions) remained the same. Supports 110 and 110′ are identical to their correspondents in FIG. 2, except that their lengths (front to back dimensions) were decreased by the same amount, while their widths (right to left dimensions) remained the same. Basically, the three members making up each of supports 110 and 110′ (corresponding to members 12, 14 and 16 of FIG. 1) were made of the same channel stock but each of their lengths were increased by the same percentage.

Accordingly, by the simple expedient of changing the lengths of components, the proportions of the assembly of FIG. 5 were easily changed. In the embodiment of FIG. 5 the support to support spacing and the effective length of the support is transposed relative to that shown in FIG. 2. Therefore, the photovoltaic panel 20 that will fit in the assembly of FIG. 2 will fit in the assembly of FIG. 5 if rotated 90°. Stated another way, the assembly of FIG. 2 holds the panel 20 in the landscape orientation, while the assembly of FIG. 5 will hold the panel in the portrait orientation.

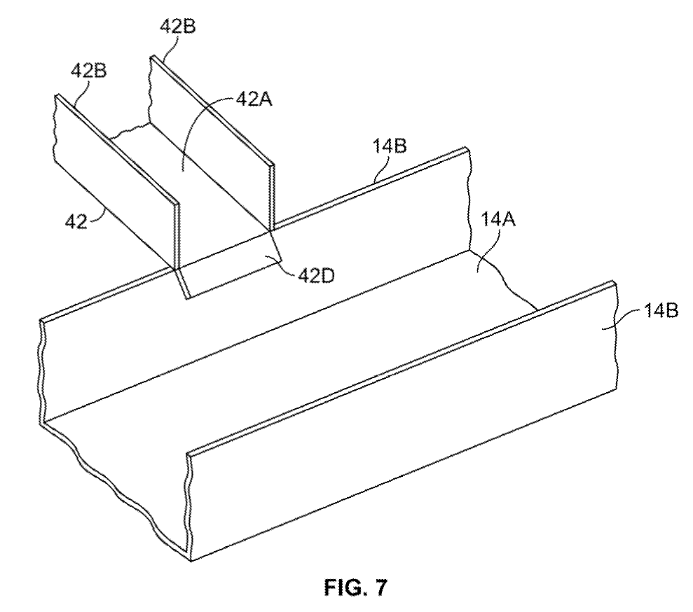

Referring to FIGS. 6 and 7, previously mentioned auxiliary tray 26 has been attached to a different portion of support 10. Instead of being attached to flange 14B, ears 26C on the right end of auxiliary tray 26 are shown attached to flange 12B. It will be understood that the left end of tray 26 will be attached in a similar fashion to a corresponding flange of previously mentioned support 12′ (FIG. 1).

This repositioning of auxiliary tray 26 elevates the tray and makes room for optional wire tray 42, which is a channel having web 42A integral with flanges 42B. On both ends, flanges 42B are cut short and web 42A is extended and bent down into lip 42D, which hooks over the edge of flange 14B. Wires (not shown) may be routed through tray 42. Since web 42A is higher than member 14 these wires will not need to penetrate through member 14 by using any of the knockouts (e.g., knockouts 14C of FIG. 1). It will be appreciated that trays identical to tray 42 may be positioned between successive supports to provide a means for routing wires from one side of an array to the other.

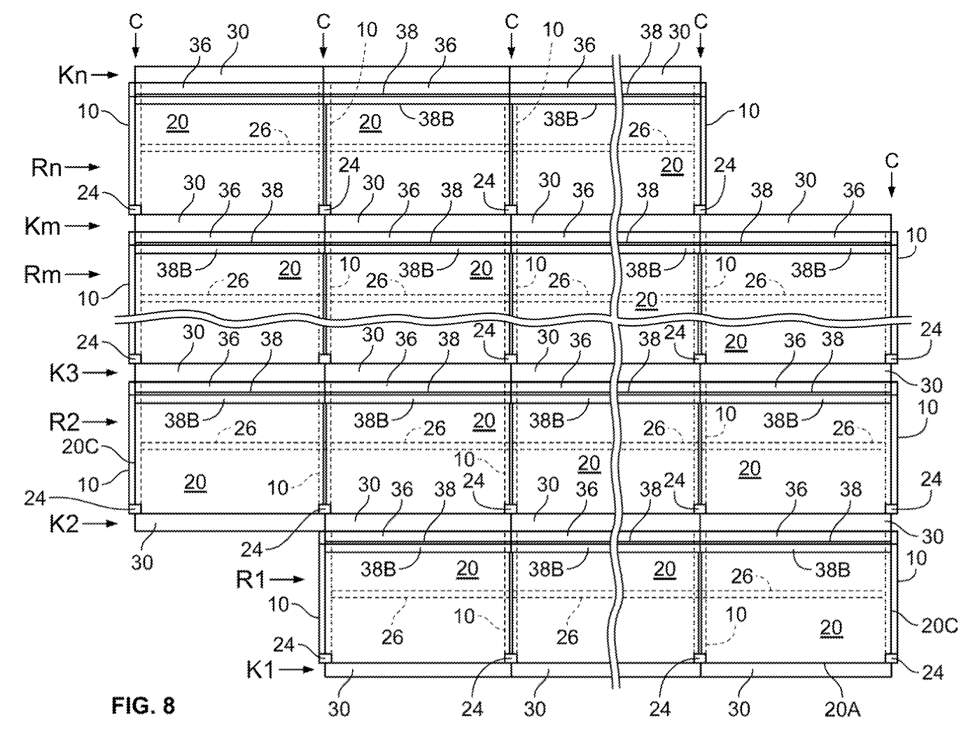

To facilitate an understanding of the principles associated with the foregoing apparatus, the operation of the embodiment of FIGS. 1-4 will be briefly described in connection with the plan view of the photovoltaic array shown in FIG. 8. In FIG. 8 a large number of photovoltaic panels with associated supports are shown. To simplify the presentation, identical components will bear the same reference numerals (i.e. the prime notation will be eliminated unless necessary).

The array of FIG. 8 may be considered a mosaic of photovoltaic assemblies, where all of the elements of the mosaic fit into a grid composed of aligned rows and columns. Therefore, any outline can be achieved subject to the granularity caused by the reticulation imposed by a mosaic. For example, if one wished to have an edge that proceeds at 45°, the resulting edge would be a staircase-like shape. One can achieve edges proceeding at different angles by changing the proportions of the “step” and “riser.”

The array shown in FIG. 8 is essentially rectangular except that no photovoltaic panels appear in the upper right and lower left corners. Such an arrangement may be needed when there is an obstruction in those corners; for example, air-conditioning equipment or a ventilation pipe protruding through a roof. In some cases an obstruction may exist near the center of an array, in which case one or more photovoltaic panels 20 may be eliminated.

When eliminating these panels 20 one may or may not remove the supports 10 and trays 30 otherwise associated with a panel. For example, if just a single panel is eliminated, one would not eliminate any of the supports 10 or the trays 30. Removal of the wind deflecting structure 36/38 otherwise located at the back of the eliminated panel is optional. In fact when removing a greater number of panels 20, if the obstructions will permit, one may still keep in the panel-free area, some (or all) of the supports 10 and some (or all) of the other associated trays 30 simply to provide ballast and a physical interconnection across the opening in the array. Otherwise, supports 10 unneeded for panel support may be removed and trays 30 may be removed from the panel-free region.

In any event, in the embodiment of FIG. 8, supports 10, trays 30 and deflector assemblies 36/38 will be interconnected as shown in FIGS. 1-4 in order to build up the array. Supports 10 will be assembled at the factory and trays 30 may be connected in the field at opposite ends of the supports 10 using pop rivets or other types of fasteners. Likewise, auxiliary trays 26 may be installed between supports 10 using the same type of fasteners. It may be convenient to place ballast weights 40 in trays 30 and 26 at this time before installing photovoltaic panels 20.

After bending up tab 12E (FIG. 4) photovoltaic panels 20 may now be placed straddling an adjacent pair of supports 10 with the front edge of the panel resting in the hook formed by elements 22 and 24 (see FIG. 1). Panels 20 may also be wired and cables from them can be routed in throughholes created in the supports 10 after removing knockouts 12C or 14C. Alternatively, one can use the optional wire tray 42 as shown in FIG. 6.

Next, wall 36 can be riveted to the adjacent pair of supports 10 (see rivet 37 in FIG. 3) before riveting holder 38 onto this same adjacent pair of supports (see rivet 39 FIG. 3). Accordingly, panel 20 will be held in position on its side edges 20C by tabs 12E, on its front edge by the two hooks 22/24, and on its back edge by the holder 38. Significantly, this mounting structure has the advantage that one will not need to bolt directly to photovoltaic panels 20.

The array can be extended to the right, left, back or front as suggested by FIGS. 1 and 2. As shown in FIG. 1, additional tray 30′ can be attached to member 16′ in alignment with tray 30. Similarly, another tray can be attached to front plate 22′ in alignment with tray 30″. These two additional trays are attached to support 10′ and attach to another support (not shown) to the left. The foregoing technique can be applied to the right side of support 10 to connect to an additional support through additional trays.

Accordingly, trays similar to trays 30 can be extended indefinitely to the right and left on either the front or back of supports 10. Additional supports similar to support 10 can be attached to the trays' exposed flanges (flange 30A or 308 in FIG. 1). The free ends of these newly installed supports can again be interconnected with trays similar to tray 30.

In FIG. 8, after connecting trays 30 to the front and back of an adjacent pair of supports 10 photovoltaic panels 20 can be installed on them by using hook 24 and installing wall 36 and holder 38 at the panel in the manner previously described. By repeating this process one can expand the array of photovoltaic panels indefinitely in any direction to create any outline desired, within the limits imposed by reticulation as previously noted.

Consequently, the array of FIG. 8 has its supports 10 aligned in a number of columns C. Also, photovoltaic panels 20 are aligned in a number of spaced rows R1, R2, Rm, Rn. Interleaved with these rows are a number of ranks of trays 30, identified herein as ranks K1, K2, K3, . . . Km, Kn.

Since all the photovoltaic panels 20 in row R1 are in front, row R1 is considered a frontal row and the trays 30 in rank K1 front trays. No other panels are positioned in front of the leftmost photovoltaic panel 20 in row R2 and, in that sense, that portion of row R2 is also considered a frontal row and the one tray 30 in front of that panel would be considered a front tray. Trays 30 are considered intervening trays (as well as back trays) if they connect (through supports 10) on each of their flanges 30B and 30C to two panels 20 in adjacent rows.

Since all of the photovoltaic panels 20 in row Rn are in back, row Rn is considered a back row and the trays 30 in rank Kn back trays. No other panels are positioned behind the rightmost photovoltaic panel 20 in row Rm and, in that sense, that part of row Rm is also considered a back row and the one tray 30 behind that panel would be considered a back tray.

The greatest number of photovoltaic panels 20 can be installed on a rectangular roof by keeping the edges 20A/20B of the panels parallel to sides of the roof. On the other hand, each of the photovoltaic panels 20 will get the most exposure to the sun when the front edge 20A of panel 20 faces south (in the Northern Hemisphere). Often a building will not have a side facing south and a compromise is necessary because normally having an array angularly skewed relative to the building is generally undesirable.

Wind deflection is provided by components 36/38. Also, since wall 36 is disposed at an angle of about 60° from the horizontal, wind forces bearing on that wall tend to press the supports 10 downwardly, thereby keeping the array more secure. Moreover, there is substantially no gap between adjacent wind deflectors 36/38 since they are joined end to end on a common member (i.e., member 16 of FIG. 1). Likewise there is no gap on the top or bottom of wind deflectors 36/38. As result, wind is prevented from bypassing deflectors 36/38 and traveling under photovoltaic panels 20 where the wind could create an uplifting force that would tend to destabilize the array.

In any event, an appropriate amount of weight must be placed in trays 30 and optional tray 26 to keep the array securely in place. Excessive weight should not be placed in trays 30 and 26 so as to avoid the risk of overloading the roof. Overloading tends to occur from the combined weight of the array and additional burdens imposed by heavy snows or winds. As noted previously, the array should not increase the static load on the roof by more than 5 lbs/ft² (24 kg/m²). However, it has been discovered that arrays of the foregoing type can easily meet this criteria and often do much better, e.g. producing additional loading of no more than 3 lbs/ft² (15 kg/m²).

Good stability has been achieved with the foregoing embodiment by installing a sufficient number of ballast weights 40 to produce a total weight of 28 pounds in each of the trays 30 for trays that are 58.5 inches (1.5 meters) long with the rank to ranks spacing between trays 53 inches (1.3 meters). Thus these trays 30 will contain weights producing an average linear density of 0.5 pounds per inch (85 g/mm). (As noted further hereinafter, additional weight may be required for trays along the border of the array.) In cases where optional trays 26 exist this weight can be shared between trays 26 and 30. In some embodiments ballast weights 40 may be paving stones or ordinary bricks weighing, for example, 4 pounds (1.8 kg) each, so that seven weights will be required to achieve the above-mentioned 28 pounds (12.7 kg).

It will be appreciated that the amount of ballast will be tailored to fit the specific design and the controlling governmental regulations. For doubtful cases, an assembly can be subjected to wind tests to confirm stability meeting the desired design criteria (e.g. remains stable in 120 mph winds).

The foregoing array has enhanced stability because all the supports 10 are interconnected by means of trays 30. Thus each of the supports 10 are stabilized not only by ballast weights 40 in trays 30 that connect directly to that support, but are also stabilized by ballast trays 30 that connect indirectly by a connection through one or more nearby supports. For supports 10 located some distance from the edge of the array this indirect stabilization is a obtained from all directions around the support.

On the other hand, some supports are located at the border of the array so that indirect stabilization comes essentially from one side. Basically, trays 30 on the border will have supports 10 connected on only one side of tray 30. This reduced stabilization is most important when wind is moving with a back to front component (i.e. wind bearing against deflectors 36/38). In contrast wind coming with a front to back component will ride up over the inclined surfaces of panels 20 and tend to press the structure downwardly to increase stability.

For these reasons, any of the trays 30 on the array's border that are adjacent to the back edge of a panel 20 ought to receive additional ballast weights 40. In the embodiment of FIG. 8, the affected trays 30 are all of those in rank Kn and the rightmost tray 30 in rank Km. These affected trays will typically have twice as much weight as the other trays 30; i.e., the average linear density will be twice as much, although this weight increase may be varied depending upon the overall arrangement and the risk of wind damage. In some embodiments ranks of trays that must hold more weight will be wider to accommodate that additional weight.

Light shining on photovoltaic panels 20 generate electricity in the usual manner. The foregoing structure is designed so that panels 20 can be tilted at the most desirable angle for that location, without unnecessarily increasing shadowing from back edge 20B of one panel to front edge 20A of the next panel. In the disclosed embodiment this distance from edge 20B of one panel to edge 20A of the next was around 14 inches (36 cm), which is a moderately close spacing but one that would not create substantial shadowing. Of course, the panel to panel spacing can be easily adjusted by changing the width of trays 30, which were 8 inches (20 cm) in this embodiment.

It is appreciated that various modifications may be implemented with respect to the above described embodiments. While the foregoing deflector section was shown having two parts (inclined wall and holder) in some embodiments a single integral unit will be used instead. Moreover, in still other embodiments, one of the flanges of the back tray can be extended to form the deflector section. While channels are commonly used for the supports, alternate components may be employed, such as I beams, square tubes, angle brackets, etc. Instead of rivets, components can be fastened with bolts, welded joints, clamps, joining plates, etc. Instead of placing relatively narrow hooks on the front corners of the photovoltaic panels, in other embodiments a relatively wide angle bracket may span adjacent supports and cover all of the front edge of the panel. While additional weight was placed in the trays along the rear border of an array, in other cases, additional weight may be placed in front trays or in a tray that reaches the right or left edge of the array. In some embodiments the array may have a mix of interconnected panels, with some in the portrait orientation and others in the landscape orientation.

Obviously, many modifications and variations of the present invention are possible in light of the above teachings. It is therefore to be understood that within the scope of the appended claims, the invention may be practiced otherwise than as specifically described.

1. An array of photovoltaic assemblies comprising:
a plurality of photovoltaic panels arranged in a plurality of spaced rows, said spaced rows including a frontal one and a posterior one, each of the photovoltaic panels having a back edge, a front edge and an opposite pair of side edges;
a plurality of supports, each having a lower support surface and an upper support surface, said upper support surface being disposed at an acute angle relative to said lower support surface, said upper support surface being adapted to provide support for a neighboring pair of side edges of an adjacent pair of the photovoltaic panels located in one of the spaced rows;
at least one front tray disposed next to the front edge of the photovoltaic panels in the frontal one of the rows; and
a back structure including a plurality of back trays and a plurality of inclined deflector sections, said back trays and said inclined deflector sections being arranged together in a plurality of ranks, said plurality of ranks and said spaced rows of photovoltaic panels being interleaved, the back trays in each of the ranks being aligned, the inclined deflector sections extending up to the back edge of a corresponding one of said photovoltaic panels.

2. An array of photovoltaic assemblies according to claim 1 wherein each of said plurality of supports each comprise:
a first member providing said upper support surface;
a second member providing said lower support surface and connecting to said first member at a front joint; and
a third member spaced from said front joint and connected between said first and said second member.

3. An array of photovoltaic assemblies according to claim 2 comprising:
at least one auxiliary tray connected between an adjacent pair of the supports located in one of the ranks, said auxiliary tray being connected to the first member of the adjacent pair of the supports; and
a plurality of ballast weights distributed in said plurality of back trays, in said auxiliary tray, and in said at least one front tray.

4. An array of photovoltaic assemblies according to claim 2 comprising:
a wire tray adapted for holding wires and connected between an adjacent pair of the supports located in one of the ranks, said auxiliary tray being connected to the second member of the adjacent pair of the supports.

5. An array of photovoltaic assemblies according to claim 1 comprising a plurality of ballast weights distributed in said plurality of back trays and in said at least one front tray.

6. An array of photovoltaic assemblies according to claim 5 wherein said back trays include one or more rear ones bordered on only one side by photovoltaic panels, the rear ones of said back trays being adjacent to the back edge of one of the photovoltaic panels, the ballast weights being arranged with an average linear density in the rear ones of the back trays that is greater than average linear density existing in most of the other ones of the back trays.

7. An array of photovoltaic assemblies according to claim 1 wherein each of said supports comprises:
a hook adapted to hold a portion of the front edge of each of an adjacent pair of the photovoltaic panels, which adjacent pair are located in an associated one of the rows of the photovoltaic panels.

8. An array of photovoltaic assemblies according to claim 7 wherein each of said supports comprises:
a flexible tab adapted to be bent upwardly to act as a spacer between the adjacent pair of the photovoltaic panels being held by the hook.

9. An array of photovoltaic assemblies according to claim 1
at least one auxiliary tray connected between an adjacent pair of the supports located in one of the ranks; and
at least one wire tray adapted for holding wires and having on each end a downwardly projecting lip for hooking onto an adjacent pair of the supports located in one of the ranks.

10. An array of photovoltaic assemblies according to claim 1 wherein the inclined deflector sections in each rank are arranged close together to substantially eliminate gaps in order to reduce wind traveling under the photovoltaic panels.

11. An array of photovoltaic assemblies according to claim 10 wherein said back trays each comprise:
a lower trough section connected on opposite sides to two pairs of said supports, each pair being located in a different one of the rows of photovoltaic panels, said inclined deflector section being attached to said trough section and to one of said two pairs of said supports.

12. An array of photovoltaic assemblies according to claim 11 wherein said inclined deflector section comprises:
an inclined wall attached to an adjacent pair of said supports; and
an upper holder attached to said inclined wall and having an overhang for gripping the back edge of a corresponding one of said photovoltaic panels.

13. An array of photovoltaic assemblies according to claim 1 wherein intervening ones of said back trays locked between an adjacent pair of the rows of photovoltaic panels are attached on opposite sides to at least two of the supports that are located in different ones of said adjacent pair of the rows.

14. An array of photovoltaic assemblies according to claim 13 wherein the intervening ones of said back trays attach to two pairs of supports, each of the two pairs of supports being located in different ones of said adjacent pair of the rows, said intervening ones of said back trays being attached to interconnect most of the supports for the photovoltaic panels of said adjacent pair of the rows.

15. An array of photovoltaic assemblies according to claim 14 wherein the plurality of supports are aligned in a plurality of columns, the intervening ones of said back trays having a length corresponding to column to column spacing among said supports.

16. An array of photovoltaic assemblies according to claim 15 wherein adjacent, aligned pairs of said back trays are either overlapping or substantially abutting.

17. An array of photovoltaic assemblies according to claim 15 wherein the at least one front tray comprises a plurality of front trays, each of the front trays attaching to an adjacent pair of the supports in the frontal one of the rows of photovoltaic panels, said front trays being attached to interconnect most of the supports for the photovoltaic panels of the frontal one of the rows.

18. An array of photovoltaic assemblies according to claim 1 comprising:
at least one auxiliary tray connected between an adjacent pair of the supports in one of the ranks.

19. An array of photovoltaic assemblies according to claim 1 wherein said at least one front tray comprises a plurality of front trays, each identical to each one of the plurality of back trays, the plurality of supports being aligned in a plurality of columns, each of the plurality of back trays spanning an adjacent pair of said columns, each of the plurality of front trays spanning an adjacent pair of said columns.

20. An array of photovoltaic assemblies comprising:
a plurality of photovoltaic panels arranged in a plurality of spaced rows, said spaced rows including a frontal one and a posterior one, each of the panels having a back edge, a front edge and an opposite pair of side edges;
a plurality of back trays arranged in a plurality of ranks, said plurality of ranks and said spaced rows of photovoltaic panels being interleaved, the back trays in each of the ranks being aligned; and
a plurality of supports, each including:
(a) a first member having an upper support surface adapted to provide support for a neighboring pair of side edges of an adjacent pair of the photovoltaic panels located in one of the spaced rows;
(b) a second member with a lower support surface disposed at an acute angle relative to said upper support surface, and connecting to said first member at a front joint; and
(c) a third member spaced from said front joint and connected between said first and said second member.
